(19) United States
(12) Patent Application Publication
(10) Pub. No.: US 2024/0423069 A1
(43) Pub. Date: Dec. 19, 2024

(54) ELECTROLUMINESCENT DISPLAY DEVICE

(71) Applicant: LG Display Co., Ltd., Seoul (KR)

(72) Inventors: Seokho SHIM, Paju-si (KR); Yuseok JUNG, Seoul (KR)

(73) Assignee: LG Display Co., Ltd., Seoul (KR)

(21) Appl. No.: 18/745,280

(22) Filed: Jun. 17, 2024

(30) Foreign Application Priority Data
Jun. 16, 2023 (KR) 10-2023-0077443

(51) Int. Cl. H10K 59/80; H10K 102/10

(52) U.S. Cl. CPC H10K 59/8731; H10K 59/80517; H10K 2102/103

(57) ABSTRACT

An electroluminescent display device in one example includes a substrate having a display area and a non-display area adjacent to the display area, a plurality of transistors disposed in the display area on the substrate, and a light emitting diode connected to the plurality of transistors and including an anode, an emission layer, and a cathode, an encapsulation layer disposed on the light emitting diode, and a plurality of structures disposed in the non-display area on the substrate. The encapsulation layer can include a first inorganic encapsulation layer, an organic encapsulation layer disposed on the first inorganic encapsulation layer, and a second inorganic encapsulation layer disposed on the organic encapsulation layer. Each of the first inorganic encapsulation layer and the second inorganic encapsulation layer is separated with respect to a first structure disposed in an outermost region of the substrate among the plurality of structures.

### CROSS-REFERENCE TO RELATED APPLICATIONS

This application claims priority to Korean Patent Application No. 10-2023-0077443 filed on Jun. 16, 2023, in the Korean Intellectual Property Office, the entire contents of which is hereby expressly incorporated by reference into the present application.

### BACKGROUND

### Field

The present disclosure relates to an electroluminescent display device, and more particularly, to an electroluminescent display device in which the propagation of cracks which can occur in an outer region is suppressed.

### Discussion of the Related Art

The application of a liquid crystal display device (LCD) and an organic light emitting display device (OLED), which have been widely used, is gradually increasing.

The LCD and the OLED have a limitation in reducing the size of a bezel area which is visibly recognized by a user as an area in which an image is not displayed. For example, in the case of the LCD, a sealant needs to be used to seal liquid crystals and bond an upper substrate and a lower substrate. Thus, there is a limitation in reducing the size of the bezel area.

Further, in the case of the OLED, an organic light emitting diode is made of an organic material which is vulnerable to moisture or oxygen. Thus, an encapsulation unit needs to be disposed to protect the organic light emitting diode. As such, there can be a limitation in reducing the size of the bezel area. Particularly, it is impossible to implement a very large screen with one panel.

Accordingly, when the very large screen is implemented by disposing a plurality of liquid crystal display panels or a plurality of organic light emitting display panels in the form of tiles, a bezel area between adjacent panels can be visibly recognized by a user.

### SUMMARY OF THE DISCLOSURE

An object to be achieved by the present disclosure is to provide an electroluminescent display device in which an inorganic layer is separated by placing a structure in an outer region and, thus, the propagation of cracks can be suppressed, minimized or eliminated.

Another object to be achieved by the present disclosure is to provide an electroluminescent display device in which an inorganic layer is separated in a display area and a non-display area and, thus, moisture permeation can be suppressed, minimized or eliminated.

Yet another object to be achieved by the present disclosure is to provide an electroluminescent display device in which a non-display area can be reduced and, thus, a bezel area can be reduced and reliability can be improved.

Objects of the present disclosure are not limited to the above-mentioned objects, and other objects, which are not mentioned above, can be clearly understood by those skilled in the art from the following descriptions.

According to an aspect of the present disclosure, there is provided an electroluminescent display device. The electroluminescent display device comprises a substrate including a display area and a non-display area enclosing or adjacent to the display area, a plurality of transistors disposed in the display area on the substrate, a light emitting diode connected to the plurality of transistors and including an anode, an emission layer, and a cathode, an encapsulation layer disposed on the light emitting diode and including a first inorganic encapsulation layer, an organic encapsulation layer disposed on the first inorganic encapsulation layer, and a second inorganic encapsulation layer disposed on the organic encapsulation layer, and a plurality of structures disposed in the non-display area on the substrate. Each of the first inorganic encapsulation layer and the second inorganic encapsulation layer is separated with respect to a first structure disposed in an outermost region of the substrate among the plurality of structures.

According to another aspect of the present disclosure, there is provided an electroluminescent display device. The electroluminescent display device comprises a substrate including a display area and a non-display area enclosing or adjacent to the display area. The electroluminescent display device comprises a plurality of transistors disposed in the display area on the substrate. The electroluminescent display device comprises a light emitting diode connected to the plurality of transistors and including an anode, an emission layer, and a cathode. The electroluminescent display device comprises an encapsulation layer disposed on the light emitting diode and including a first inorganic encapsulation layer, an organic encapsulation layer disposed on the first inorganic encapsulation layer, and a second inorganic encapsulation layer disposed on the organic encapsulation layer. The electroluminescent display device comprises an undercut structure disposed in an outermost region of the substrate in the non-display area. Each of the first inorganic encapsulation layer and the second inorganic encapsulation layer is separated with respect to the undercut structure.

Other detailed matters of the example embodiments are included in the detailed description and the drawings.

According to aspects of the present disclosure, it is possible to suppress the propagation of cracks occurring in an outer region to a display area.

According to aspects of the present disclosure, it is possible to reduce a bezel area of an electroluminescent display device and also possible to suppress moisture permeation.

According to aspects of the present disclosure, it is possible to improve the reliability of the electroluminescent display device and thus possible to improve a lifespan of the electroluminescent display device. Therefore, it is possible to implement low power consumption.

According to aspects of the present disclosure, it is possible to secure a process margin for an inorganic layer disposed in an outer region of the display area.

The effects according to aspects of the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of a tiling display device according to an example embodiment of the present disclosure;

FIG. 2 is a schematic plan view of an electroluminescent display device according to an example embodiment of the present disclosure;

FIG. 3 is a cross-sectional view of a sub-pixel of the electroluminescent display device according to an example embodiment of the present disclosure;

FIG. 4 is a schematic cross-sectional view taken along line IV-IV′ of FIG. 2;

FIG. 5 is a schematic cross-sectional view taken along line V-V′ of FIG. 2;

FIG. 6 is a cross-sectional view for describing a method of manufacturing an electroluminescent display device according to an example embodiment of the present disclosure; and

FIG. 7 is a cross-sectional view of an electroluminescent display device according to another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification.

Further, in the following description of the present disclosure, a detailed explanation of known related technologies can be omitted to avoid unnecessarily obscuring the subject matter of the present disclosure. The terms such as “comprising,” “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

Further, the term “can” encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other. Furthermore, all the components of each electroluminescent display device according to all embodiments of the present disclosure are operatively coupled and configured.

Hereinafter, an electroluminescent display device according to example embodiments of the present disclosure will be described in detail with reference to accompanying drawings.

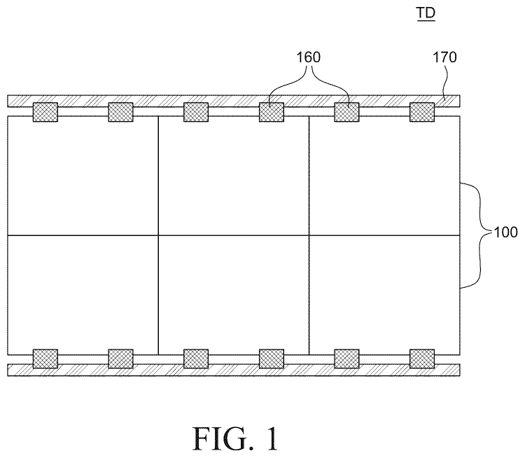

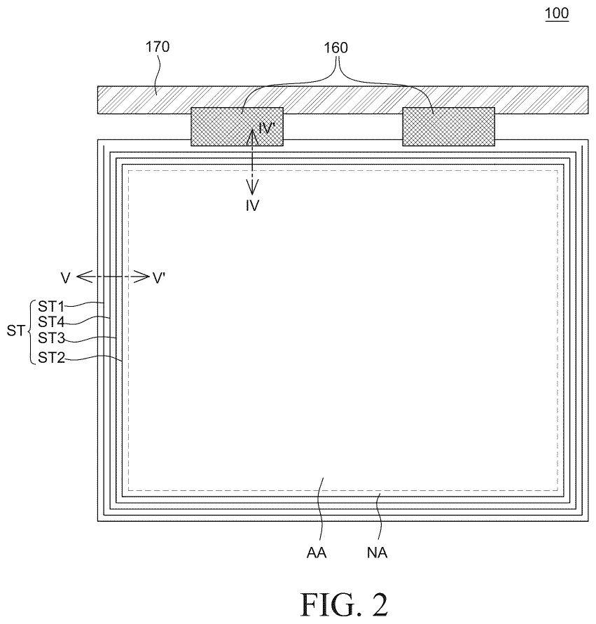

FIG. 1 is a schematic plan view of a tiling display device according to an example embodiment of the present disclosure. FIG. 2 is a schematic plan view of an electroluminescent display device according to an example embodiment of the present disclosure.

Referring to FIG. 1, a tiling display device TD according to an example embodiment of the present disclosure can include a plurality of electroluminescent display devices 100.

The plurality of electroluminescent display devices 100 can be disposed in the form of tiles to implement a single tiling display device 100. As an example, FIG. 1 illustrates that the electroluminescent display devices 100 are disposed in the form of a 2×3 tile array, for the convenience of description. However, the present disclosure is not limited thereto. The electroluminescent display devices 100 can be tiled in two rows. An end portion of the electroluminescent display device 100 on which a flexible film 160 and a printed circuit board 170 are disposed has a large width. Thus, when the electroluminescent display devices 100 are tiled by coupling the end portions thereof, a wide bezel can be recognized by a user. Thus, the plurality of electroluminescent display devices 100 can be tiled to be adjacent to each other by coupling portions excluding the portions where the flexible film 160 and the printed circuit board 170 are disposed.

The electroluminescent display device 100 can include a substrate 101.

The substrate 101 includes a display area (or active area) AA and a non-display area (or non-active area) NA.

The display area AA is an area for displaying images. A plurality of sub-pixels for displaying images and a pixel circuit for driving the plurality of sub-pixels can be disposed in the display area AA. Each of the plurality of sub-pixels is an individual unit that emits light, and can be provided with a light emitting diode (LED). The plurality of sub-pixels can include a red sub-pixel, a green sub-pixel, a blue sub-pixel, and a white sub-pixel, but is not limited thereto. The pixel circuit can include various transistors, storage capacitors, and lines for driving the plurality of sub-pixels. For example, the pixel circuit can be composed of various components, such as a driving transistor, a switching transistor, a sensing transistor, a storage capacitor, a gate line, a data line, and the like, but is not limited thereto.

The non-display area NA is an area where no image is displayed. The non-display area NA can be disposed to enclose the display area AA entirely or only in part. In the non-display area NA, various lines, driver circuits, and the like for driving the sub-pixels disposed in the display area AA are disposed. For example, driver circuits, such as a gate driver circuit, and various lines and a plurality of pads can be disposed in the non-display area NA. However, the present disclosure is not limited thereto. The electroluminescent display devices 100 can be implemented as the tiling display device TD. Therefore, the components can be disposed to minimize the size of the non-display area NA.

Referring to FIGS. 1 and 2, a plurality of flexible films 160 is connected to an end of the electroluminescent display device 100. Each of the plurality of flexible films 160 is a film in which various components are disposed on a base film having malleability. The plurality of flexible films 160 serves to supply signals to the plurality of sub pixels disposed in the display area AA. The plurality of flexible films 160 can be disposed at one end of the non-display area NA of the electroluminescent display device 100 to supply a data voltage or the like to the plurality of sub pixels disposed in the display area AA.

A driver unit, such as a gate driver and a data driver, can be disposed on the plurality of flexible films 160. The driver unit can be mounted by a Chip On Glass (COG) method, a Chip On Film (COF) method or a Tape Carrier Package (TCP) method depending on a mounting method, but is not limited thereto.

Meanwhile, the shape and the number of the plurality of flexible films 160 shown in FIGS. 1 and 2 are merely an example, and are not limited thereto. The shape and the number of the plurality of flexible films 160 can be modified variously depending on the design.

Referring to FIGS. 1 and 2, the printed circuit board 170 is connected to the plurality of flexible films 160. The printed circuit board 170 is a component configured to supply signals to a driver integrated circuit (IC). Various components configured to supply various driving signals, such as a driving signal, a data voltage, etc., to the driver IC can be disposed on the printed circuit board 170.

Referring to FIG. 2, the electroluminescent display device 100 can include a plurality of structures ST. The plurality of structures ST can be disposed in the non-display area NA of the substrate 101.

The plurality of structures ST can include a first structure ST1, a second structure ST2, a third structure ST3, and a fourth structure ST4.

The first structure ST1 can be disposed in an outermost region of the substrate 101.

The first structure ST1 can be disposed on the other surfaces of the substrate 101 except the surface on which the flexible films 160 are disposed. For example, as shown in FIG. 2, the first structure ST1 can be disposed on three side surfaces of the electroluminescent display device 100 on which the flexible films 160 are not disposed among four side surfaces of the electroluminescent display device 100. However, the present disclosure is not limited thereto.

The second structure ST2 can be disposed in the non-display area NA so as to be most adjacent to the display area AA among the plurality of structures ST. The third structure ST3 can be disposed outside the second structure ST2, and the fourth structure ST4 can be disposed between the third structure ST3 and the first structure ST1.

The second structure ST2, the third structure ST3, and the fourth structure ST4 can be disposed in the non-display area NA so as to enclose the display area AA. For example, the second structure ST2, the third structure ST3, and the fourth structure ST4 can be disposed in a closed loop shape as shown in FIG. 2.

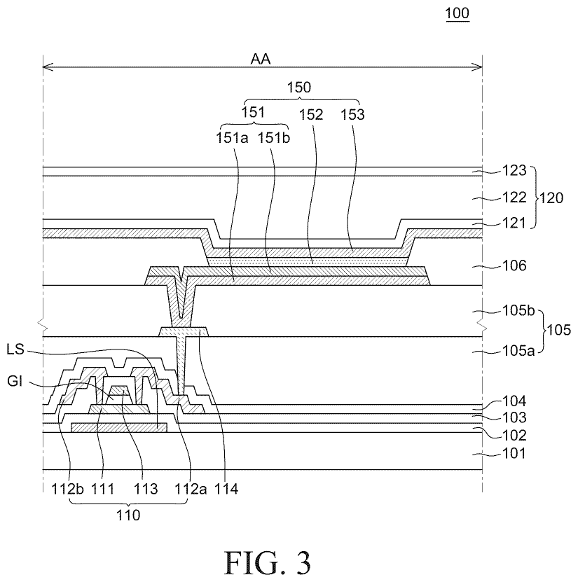

Details of the plurality of structures ST will be described below with reference to FIGS. 3 to 5.

FIG. 3 is a cross-sectional view of a sub-pixel of the electroluminescent display device according to an example embodiment of the present disclosure. Particularly, FIG. 3 is a cross-sectional view of a sub-pixel of the electroluminescent display device 100 according to an example embodiment of the present disclosure.

Referring to FIG. 3, the electroluminescent display device 100 according to an example embodiment of the present disclosure can include the substrate 101, a transistor 110, a light shielding layer LS, a buffer layer 102, and a gate insulating layer GI. The electroluminescent display device 100 can include an interlayer insulating layer 103, a passivation layer 104, a planarization layer 105, a light emitting diode 150, a bank 106, and an encapsulation layer 120.

The substrate 101 is a support member for supporting other components of the electroluminescent display device 100, and can be made of an insulating material. For example, the substrate 110 can be made of glass or resin. Further, the substrate 110 can be made of a polymer or plastic, such as polyimide (PI), or can be made of a material having flexibility.

The light shielding layer LS can be disposed on the substrate 101. The light shielding layer LS is disposed to overlap at least an active layer 111 of the transistor 110 and thus serves to block light incident onto the active layer 111. Although it is illustrated in the drawing that the light shielding layer LS is configured by a single layer, the light shielding layer LS can be configured by a plurality of layers. The light shielding layer LS can be made of various conductive materials, such as magnesium (Mg), aluminum (Al), nickel (Ni), chromium (Cr), molybdenum (Mo), tungsten (W), gold (Au), or an alloy thereof.

The buffer layer 102 can be disposed on the light shielding layer LS. The buffer layer 102 is a functional layer for protecting various electrodes and lines from impurities, such as alkali ions, leaking from the substrate 101 or the underlying layers. The buffer layer 102 can have a multilayer structure, but is not limited thereto. The buffer layer 102 can be configured by silicon oxide (SiOx), silicon nitride (SiNx), or a multi-layer thereof.

The buffer layer 102 can delay diffusion of moisture and/or oxygen permeating into the substrate 101. Further, the buffer layer 102 can include a multi-buffer and/or an active buffer. The active buffer serves to protect the active layer 111 composed of a semiconductor of the transistor 110 and block various types of defects introduced from the substrate 101. The active buffer can be made of amorphous silicon (a-Si), but is not limited thereto.

The transistor 110 can be disposed on the buffer layer 102. The transistor 110 can have a structure in which the active layer 111, the gate insulating layer GI, a gate electrode 113, the interlayer insulating layer 103, a source electrode 112a, and a drain electrode 112b are sequentially laminated. The transistor 110 can be electrically connected to the light emitting diode 150 through a connection electrode 114 and can serve to transmit a current or a signal to the light emitting diode 150.

The active layer 111 can be disposed on the buffer layer 102. The active layer 111 can be made of polysilicon (p-Si). In this case, a predetermined region can be doped with impurities. Alternatively, the active layer 111 can be made of amorphous silicon (a-Si), or various organic semiconductor materials, such as pentacene. Otherwise, the active layer 111 can be made of an oxide semiconductor.

The gate insulating layer GI can be disposed on the active layer 111. The gate insulating layer GI can be made of an inorganic insulating material, such as silicon oxide (Siox) or silicon nitride (SiNx), or an organic insulating material.

Particularly, FIG. 3 illustrates that the gate insulating layer GI is disposed only in an area overlapping the gate electrode 113. However, the present disclosure is not limited thereto. The gate insulating layer GI can be disposed to overlap the entire surface of the substrate 101.

The gate electrode 113 can be disposed on the gate insulating layer GI. The gate electrode 113 can be made of various conductive materials, such as magnesium (Mg), aluminum (Al), nickel (Ni), chromium (Cr), molybdenum (Mo), tungsten (W), gold (Au), or an alloy thereof.

The interlayer insulating layer 103 can be disposed on the gate electrode 113. The interlayer insulating layer 103 can be made of an insulating material, such as silicon oxide (Siox) or silicon nitride (SiNx), or an organic insulating material.

Each of the source electrode 112a and the drain electrode 112b can be configured by a single layer or a multilayer structure made of electrode materials on the interlayer insulating layer 103. The source electrode 112a and the drain electrode 112b can be connected to the active layer 111 through a contact hole provided in the interlayer insulating layer 103. The source electrode 112a and the drain electrode 112b can be made of various conductive materials, such as magnesium (Mg), aluminum (Al), nickel (Ni), chromium (Cr), molybdenum (Mo), tungsten (W), gold (Au), or an alloy thereof.

The passivation layer 104 can be disposed on the transistor 110. The passivation layer 104 is an insulating layer for protecting the underlying components. For example, the passivation layer 104 can be made of an inorganic insulating material, such as silicon oxide (Siox) or silicon nitride (SiNx), or an organic insulating material, but is not limited thereto. The passivation layer 104 can be omitted in some embodiments.

The planarization layer 105 can be disposed on the passivation layer 104. The planarization layer 105 can include a first planarization layer 105a and a second planarization layer 105b as shown in in FIG. 2, but is not limited thereto. The first planarization layer 105a and the second planarization layer 105b can contain an organic insulating material. For example, the first planarization layer 105a and the second planarization layer 105b can be made of polyimide, or acryl- or benzocyclobutene (BCB)-based resin, but is not limited thereto.

The first planarization layer 105a can be disposed to cover the transistor 110. The first planarization layer 105a can be disposed to expose parts of the source electrode 112a and the drain electrode 112b of the transistor 110.

The connection electrode 114 can be disposed on the first planarization layer 105a so as to electrically connect the transistor 110 and the light emitting diode 150. Various metal layers serving as lines/electrodes, such as data lines, signal lines, etc., can be disposed on the first planarization layer 105a.

Further, the second planarization layer 105b can be disposed on the first planarization layer 105a and the connection electrode 114. The second planarization layer 105b can be provided to expose a part of the connection electrode 114. Further, the source electrode 112a of the transistor 110 can be electrically connected to an anode 151 of the light emitting diode 150 by the connection electrode 114.

The light emitting diode 150 can have a structure in which the anode 151, an emission layer 152, and a cathode 153 are sequentially laminated. For example, the light emitting diode 150 can be composed of the anode 151 provided on the planarization layer 105, the emission layer 152 provided on the anode 151, and the cathode 153 provided on the emission layer 152.

The display device can be implemented in a top emission method or a bottom emission method. According to the top emission method, a reflective layer made of an opaque conductive material with high reflectivity can be added under the anode 151. Thus, light emitted from the emission layer 152 is reflected by the anode 151 and directed upwards, i.e., toward the cathode 153. Herein, the opaque conductive material can be, for example, silver (Ag), aluminum (Al), gold (Au), molybdenum (Mo), tungsten (W), chromium (Cr), or an alloy thereof. According to the bottom emission method, the anode 151 can be made of only a transparent conductive material, such as indium tin oxide (ITO), indium zinc oxide (IZO), indium gallium zinc oxide (IGZO), or the like. Hereinafter, it will be assumed and described that the electroluminescent display device 100 of the present disclosure is a top emission electroluminescent display device.

The anode 151 is disposed on the second planarization layer 105b. The anode 151 can correspond to each of a plurality of sub-pixels. For example, the anode 151 can be patterned so as to correspond to each of the plurality of sub-pixels. The anode 151 can be electrically connected to the connection electrode 114 and the transistor 110 through contact holes provided in the second planarization layer 105b and the first planarization layer 105a, respectively.

The anode 151 can include a first anode 151a and a second anode 151b on the first anode 151a. The first anode 151a can have a structure in which a layer made of indium tin oxide (ITO), a layer made of a molybdenum-titanium (MoTi) alloy, and a layer made of ITO are laminated. The second anode 151b can have a structure in which a layer made of ITO, a layer made of silver (Ag) or an Ag alloy, and a layer made of ITO are laminated.

A bank 106 is disposed on the anode 151 and the second planarization layer 105b. The bank 106 can be provided on the second planarization layer 105b so as to cover an edge of the anode 151.

The bank 106 is an insulating layer disposed between a plurality of sub-pixels to define the plurality of sub-pixels. The bank 106 can be an organic insulating material. For example, the bank 106 can be made of polyimide, or acryl- or benzocyclobutene (BCB)-based resin, but is not limited thereto.

The emission layer 152 is disposed on the anode 151 and the bank 106. The emission layer 152 can be provided on the entire surface of the substrate 101. For example, the emission layer 152 can be a common layer corresponding to all of the plurality of sub-pixels. The emission layer 152 can be an organic layer for emitting light of a specific color. The emission layer 152 can include various layers, such as a hole transport layer, a hole injection layer, a hole blocking layer, an electron injection layer, an electron blocking layer, an electron transport layer, etc.

The cathode 153 is disposed on the emission layer 152. The cathode 153 [symbol] the substrate 101 can be provided as a single layer on the entire surface of the substrate 101. For example, the cathode 153 can be a common layer corresponding to all of the plurality of sub-pixels. The cathode 153 supplies electrons to the emission layer 152 and thus can be made of a conductive material having a low work function. The cathode 153 can be made of a transparent conductive material, such as indium tin oxide (ITO) and indium zinc oxide (IZO), a metal alloy, such as MgAg, or an ytterbium (Yb) alloy. The cathode 153 can further include a metal doping layer. However, the present disclosure is not limited thereto.

The encapsulation layer 120 is disposed on the light emitting diode 150. The encapsulation layer 120 protects the light emitting diode 150 from moisture or the like permeating from the outside of the electroluminescent display device 100. The encapsulation layer 120 includes a first inorganic encapsulation layer 121, an organic encapsulation layer 122, and a second inorganic encapsulation layer 123.

The first inorganic encapsulation layer 121 is disposed on the cathode 153 and serves to suppress the permeation of moisture or oxygen. The first inorganic encapsulation layer 121 can be made of an inorganic material, such as silicon oxide (Siox), silicon nitride (SiNx), silicon oxynitride (SiNxOy), or aluminum oxide (AlyOz), but is not limited thereto.

The organic encapsulation layer 122 is disposed on the first inorganic encapsulation layer 121 and serves to planarize the surface of the first inorganic encapsulation layer 121. Further, the organic encapsulation layer 122 can cover foreign matters or particles which can be generated during a manufacturing process. The organic encapsulation layer 122 can be made of an organic insulating material, such as silicon oxycarbon (SiOxCz), or acryl- or epoxy-based resin, but is not limited thereto.

The second inorganic encapsulation layer 123 is disposed on the organic encapsulation layer 122. Like the first inorganic encapsulation 121, layer the second inorganic encapsulation layer 123 serves to suppress the permeation of moisture or oxygen. Herein, the second inorganic encapsulation layer 123 and the first inorganic encapsulation layer 121 can serve to seal the organic encapsulation layer 122. Therefore, moisture or oxygen permeating into the light emitting diode 150 can be effectively reduced by the second inorganic encapsulation layer 123. The second inorganic encapsulation layer 123 can be made of an inorganic material, such as silicon oxide (Siox), silicon nitride (SiNx), silicon oxynitride (SiNxOy), or aluminum oxide (AlyOz), but is not limited thereto.

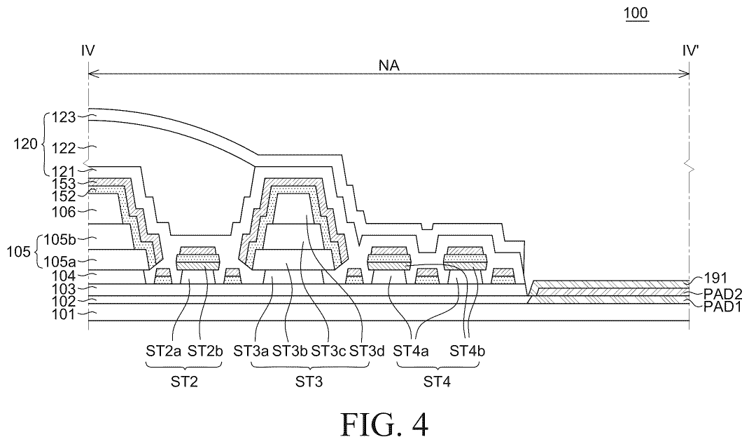

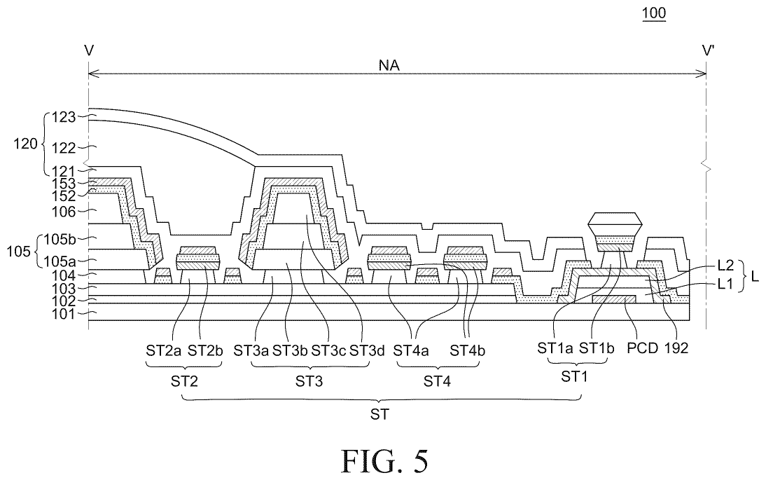

Hereinafter, the non-display area NA will be described in detail with reference to FIGS. 4 and 5.

FIG. 4 is a schematic cross-sectional view taken along line IV-IV′ of FIG. 2. FIG. 5 is a schematic cross-sectional view taken along line V-V′ of FIG. 2.

Particularly, FIG. 4 is a cross-sectional view of one surface of the substrate 101 to which the flexible film 160 is bonded. FIG. 5 is a cross-sectional view of the other surfaces of the substrate 101 except the one surface on which the flexible film 160 is disposed. FIG. 4 does not illustrate the flexible film 160 for the convenience of description.

Referring to FIGS. 4 and 5, the substrate 101, the buffer layer 102, the interlayer insulating layer 103, the passivation layer 104, the planarization layer 105, and the bank 106 can be disposed in the non-display area NA. Further, the encapsulation layer 120, a plurality of pads PAD, a crack detection unit PCD, and a plurality of inorganic layers L can be disposed in the non-display area NA. Further, a pad protection layer 191, a transparent conductive layer 192, and the plurality of structures ST can be disposed in the non-display area NA.

The plurality of structures ST can be disposed on the substrate 101, the buffer layer 102, and the interlayer insulating layer 103.

The plurality of structures ST can include the first structure ST1, the second structure ST2, the third structure ST3, and the fourth structure ST4.

The second structure ST2, the third structure ST3, and the fourth structure ST4 can be disposed in the non-display area NA so as to enclose the display area AA.

Referring to FIGS. 4 and 5, the second structure ST2 can be disposed to be most adjacent to the display area AA among the plurality of structures ST, and the third structure ST3 can be disposed outside the second structure ST2. The fourth structure ST4 can be disposed between the third structure ST3 and the first structure ST1.

The second structure ST2 and the fourth structure ST4 can suppress the permeation of moisture and oxygen from the outside. Further, the second structure ST2 and the fourth structure ST4 can minimize damage to an organic material disposed inside the electroluminescent display device 100 caused by moisture and oxygen. When the emission layer 152 is formed, it can be disconnected by an undercut shape of each of the second structure ST2 and the fourth structure ST4. Thus, a part of the emission layer 152 can be disposed on each of the second structure ST2 and the fourth structure ST4. Further, the emission layer 152 can be separated for each of the second structure ST2 and the fourth structure ST4. Therefore, it is possible to suppress the permeation of moisture and oxygen from the outside of the electroluminescent display device 100 into the display area AA through the emission layer 152 disposed in the non-display area NA. Further, the first inorganic encapsulation layer 121 and the second inorganic encapsulation layer 123 are disposed to enclose the surfaces of the second structure ST2 and the fourth structure ST4. Therefore, it is possible to delay the permeation of moisture and oxygen by increasing a permeation path of moisture and oxygen from the outside of the electroluminescent display device 100.

Herein, the second structure ST2 and the fourth structure ST4 can have the same shape. For example, the second structure ST2 and the fourth structure ST4 can have the same configuration and shape except the positions thereof. For example, each of the second structure ST2 and the fourth structure ST4 can have a structure in which the same material as the passivation layer 104 and the same material as the first anode 151a are laminated. For example, the second structure ST2 can have a structure in which a first layer ST2a made of the same material as the passivation layer 104 and a second layer ST2b made of the same material as the first anode 151a are laminated. The fourth structure ST4 can have a structure in which a first layer ST4a made of the same material as the passivation layer 104 and a second layer ST4b made of the same material as the first anode 151a are laminated. However, the materials of the second structure ST2 and the fourth structure ST4 are not limited thereto.

Further, each of the second structure ST2 and the fourth structure ST4 can have an undercut shape. Specifically, a lower surface of the second layer ST2b of the second structure ST2 can have a greater size than an upper surface of the first layer ST2a of the second structure ST2. Further, a lower surface of the second layer ST4b of the fourth structure ST4 can have a greater size than an upper surface of the first layer ST4a of the fourth structure ST4.

The third structure ST3 is configured to control a formation region of the organic encapsulation layer 122. The height of the third structure ST3 can be controlled and, thus, the third structure ST3 can serve as a dam to suppress an overflow of the organic encapsulation layer 122. Therefore, the third structure ST3 can have a greater height than the second structure ST2 and the fourth structure ST4. Accordingly, the second structure ST2 can be disposed under the organic encapsulation layer 122, and an end of the organic encapsulation layer 122 can be disposed to overlap the third structure ST3.

The third structure ST3 can have a structure in which the same material as the passivation layer 104, the same material as the planarization layer 105, and the same material as the bank 106 are laminated. For example, the third structure ST3 can have a structure in which a first layer ST3a made of the same material as the passivation layer 104, a second layer ST3b made of the same material as the first planarization layer 105a, a third layer ST3c made of the same material as the second planarization layer 105b, and a fourth layer ST3d made of the same material as the bank 106 are laminated. However, the materials of the third structure ST3 are not limited thereto.

Herein, the third structure ST3 can have an inverse tapered shape. For example, a lower surface of the second layer ST3b of the third structure ST3 can have a greater size than an upper surface of the first layer ST3a of the third structure ST3. Thus, the third structure ST3 can also suppress the permeation of moisture and oxygen from the outside of the electroluminescent display device 100 into the display area AA through the emission layer 152 disposed in the non-display area NA. Further, the third structure ST3 can delay the permeation of moisture and oxygen by increasing a permeation path of moisture and oxygen from the outside of the electroluminescent display device 100.

Particularly, FIGS. 4 and 5 illustrate that the interlayer insulating layer 103 disposed under the plurality of structures ST is continuously disposed between the plurality of structures ST. However, the present disclosure is not limited thereto. The interlayer insulating layer 103 can be discontinuously disposed between the plurality of structures ST.

The emission layer 152 and the cathode 153 can be disposed on the plurality of structures ST. The emission layer 152 and the cathode 153 can be separated for each of the plurality of structures ST. For example, the emission layer 152 and the cathode 153 can be discontinuously disposed between the plurality of structures ST so as to cover parts of an upper surface of the interlayer insulating layer 103 between the plurality of structures ST. However, the present disclosure is not limited thereto.

The encapsulation layer 120 including the first inorganic encapsulation layer 121, the organic encapsulation layer 122, and the second inorganic encapsulation layer 123 can be disposed on the cathode 153.

The first inorganic encapsulation layer 121 can extend from the display area AA to the non-display area NA.

The organic encapsulation layer 122 is disposed on the first inorganic encapsulation layer 121 and disposed in the display area AA and a part of the non-display area NA extending from the display area AA. For example, the organic encapsulation layer 122 can be disposed inside the third structure ST3.

The second inorganic encapsulation layer 123 can extend from the display area AA to the non-display area NA. The second inorganic encapsulation layer 123 can be in contact with the first inorganic encapsulation layer 121 outside the end of the organic encapsulation layer 122. For example, the second inorganic encapsulation layer 123 can be in contact with the first inorganic encapsulation layer 121 outside the third structure ST3.

Referring to FIGS. 4 and 5, each of the first inorganic encapsulation layer 121 and the second inorganic encapsulation layer 123 can be continuously disposed to be in contact with the surfaces of the second structure ST2, the third structure ST3, and the fourth structure ST4. For example, each of the first inorganic encapsulation layer 121 and the second inorganic encapsulation layer 123 can extend from the display area AA to a region overlapping the surface of the fourth structure ST4.

Referring to FIG. 4, the plurality of pads PAD is disposed outside the plurality of structures ST on one surface of the substrate 101. The plurality of flexible films 160 can be disposed on the plurality of pads PAD as shown in FIG. 2.

The plurality of pads PAD can include a first pad PAD1 and a second pad PAD2 on the first pad PAD1.

The first pad PAD1 can be made of the same material as the active layer 111. However, a semiconductor material of the first pad PAD1 can be conductive, but is not limited thereto.

The second pad PAD2 can be made of the same material as the source electrode 112a and the drain electrode 112b. For example, the second pad PAD2 can be made of various conductive materials, such as magnesium (Mg), aluminum (Al), nickel (Ni), chromium (Cr), molybdenum (Mo), tungsten (W), gold (Au), or an alloy thereof. However, the present disclosure is not limited thereto.

The pad protection layer 191 can be disposed to enclose the plurality of pads PAD. The pad protection layer 191 can be made of the same material as the transparent conductive layer 192 disposed under the first structure ST1 on the substrate 101. For example, the pad protection layer 191 can be made of a transparent conductive material, such as indium tin oxide (ITO) and indium zinc oxide (IZO), but is not limited thereto.

Referring to FIG. 5, the crack detection unit PCD can be disposed outside the fourth structure ST4 on the substrate 101. The crack detection unit PCD can be disposed outside the fourth structure ST4 so as to enclose the display area AA. However, the present disclosure is not limited thereto.

The crack detection unit PCD can be made of the same material as the light shielding layer LS. For example, the crack detection unit PCD can be made of various conductive materials, such as magnesium (Mg), aluminum (Al), nickel (Ni), chromium (Cr), molybdenum (Mo), tungsten (W), gold (Au), or an alloy thereof. However, the present disclosure is not limited thereto.

The crack detection unit PCD can be disposed under the first structure ST1 so as to overlap the first structure ST1.

The plurality of inorganic layers L can be disposed on the crack detection unit PCD. The plurality of inorganic layers L can be disposed between the crack detection unit PCD and the first structure ST1 so as to cover side and upper surfaces of the crack detection unit PCD.

The plurality of inorganic layers L can be made of the same material as an inorganic insulating layer disposed in the display area AA. For example, the plurality of inorganic layers L can include a first inorganic layer L1 made of the same material as the buffer layer 102 and a second inorganic layer L2 disposed on the first inorganic layer L1 and made of the same material as the interlayer insulating layer 103. Thus, the first inorganic layer L1 and the second inorganic layer L can be made of an inorganic insulating material, such as silicon oxide (Siox) or silicon nitride (SiNx). However, the present disclosure is not limited thereto.

The transparent conductive layer 192 can be disposed between the plurality of inorganic layers L and the first structure ST1 on the substrate 101. The transparent conductive layer 192 can be disposed between the plurality of inorganic layers L and the first structure ST1 on the substrate 101. Further, the transparent conductive layer 192 can be disposed to enclose upper and side surfaces of the plurality of inorganic layers L disposed on the crack detection unit PCD, and can be disposed to be in contact with an upper surface of the substrate 101. For example, the transparent conductive layer 192 can extend from the upper and side surfaces of the plurality of inorganic layers L so as to cover a part of the upper surface of the substrate 101. However, the present disclosure is not limited thereto.

The transparent conductive layer 192 serves to suppress damage to the plurality of inorganic layers L disposed under the transparent conductive layer 192 when the components disposed on the transparent conductive layer 192 are etched. Thus, the transparent conductive layer 192 can serve as an etch stopper. The transparent conductive layer 192 can be made of a transparent conductive material, such as indium tin oxide (ITO) and indium zinc oxide (IZO), but is not limited thereto.

The first structure ST1 can be disposed on the other surfaces of the substrate 101 except the surface on which the flexible films 160 are disposed, as shown in FIG. 1. Among the plurality of structures ST, the first structure ST1 can be disposed in an outermost region of the substrate 101.

Referring to FIG. 5, the first structure ST1 includes a first layer ST1a and a second layer ST1b on the first layer ST1a. A lower surface of the second layer ST1b can have a greater size than an upper surface of the first layer ST1a. Thus, the first structure ST1 can be referred to as an undercut structure.

The first layer ST1a can be made of the same material as an insulating layer covering upper portions of a plurality of transistors 110, and the second layer STlb can be made of the same material as the anode 151. For example, the first layer ST1a can be made of the same material as the passivation layer 104. For example, the first layer ST1a can be made of an inorganic insulating material, such as silicon oxide (Siox) or silicon nitride (SiNx). The second layer ST1b can be made of the same material as the first anode 151a. For example, the second layer ST1b can have a structure in which a layer made of indium tin oxide (ITO), a layer made of a molybdenum-titanium (MoTi) alloy, and a layer made of ITO are laminated. However, the present disclosure is not limited thereto.

Herein, each of the first inorganic encapsulation layer 121 and the second inorganic encapsulation layer 123 can be separated with respect to the first structure ST1 disposed in the outermost region among the plurality of structures ST. The first inorganic encapsulation layer 121 and the second inorganic encapsulation layer 123 disposed on the transparent conductive layer 192 can be respectively separated from the first inorganic encapsulation layer 121 and the second inorganic encapsulation layer 123 disposed on the first layer ST1a of the first structure ST1.

Referring to FIG. 5, an end of the substrate 101 can overlap an end of the emission layer 152, an end of the first inorganic encapsulation layer 121, and an end of the second inorganic encapsulation layer 123. For example, the end of the substrate 101 can be disposed on the same plane as the end of the emission layer 152, the end of the first inorganic encapsulation layer 121, and the end of the second inorganic encapsulation layer 123.

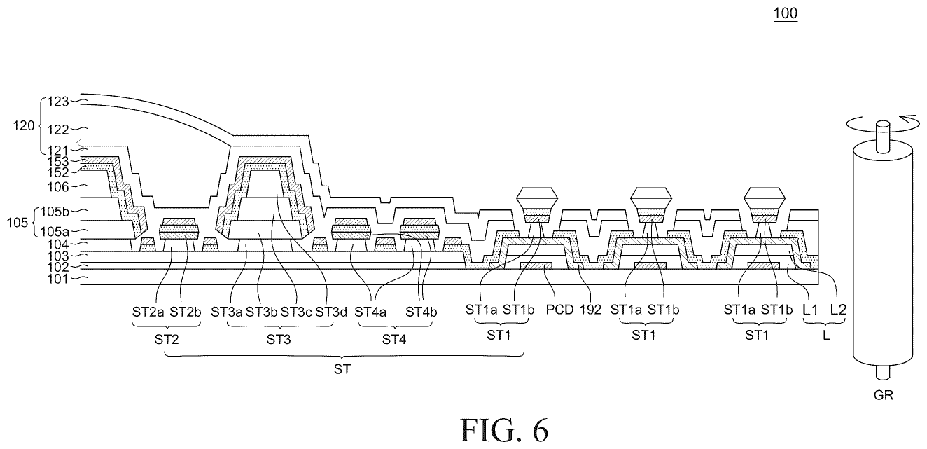

Hereinafter, a method of manufacturing an electroluminescent display device according to an example embodiment of the present disclosure will be described with reference to FIG. 6.

FIG. 6 is a cross-sectional view for describing the method of manufacturing an electroluminescent display device according to an example embodiment of the present disclosure. Particularly, FIG. 6 is a cross-sectional view of the other surfaces of the substrate 101 except the one surface on which the flexible films 160 are disposed.

Referring to FIG. 6, the plurality of structures ST can be disposed in the non-display area NA. The plurality of structures ST can include the first structure ST1, the second structure ST2, the third structure ST3, and the fourth structure ST4. Herein, in a manufacturing process of the electroluminescent display device 100 according to an example embodiment of the present disclosure, the first structure ST1 can be provided in plurality. FIG. 6 illustrates three first structures ST1. However, the number of first structures ST1 is not limited thereto.

A grinder GR disposed outside the substrate 101 can grind a side surface of the substrate 101 while rotating about a rotational axis. The grinder GR can grind the substrate 101 as well as the plurality of first structures ST1 on the substrate 101 to the same size as the electroluminescent display device 100.

After the grinding process is finished, the end of the emission layer 152 and the ends of the first inorganic encapsulation layer 121 and the second inorganic encapsulation layer 123 disposed on the first structure ST1 can be disposed on the same plane as the end of the substrate 101, as shown in FIG. 5.

As for an organic light emitting display device, an organic light emitting diode is made of an organic material and thus is very vulnerable to moisture or oxygen. Thus, an encapsulation layer for protecting the organic light emitting diode needs to be disposed. Therefore, there is a limitation in reducing the size of a bezel area. For example, in a process of grinding a substrate to the same size as the display device, the substrate is ground from the outside of an inorganic layer to suppress the occurrence and propagation of cracks in the inorganic layer. For example, in order for the inorganic layer not to be ground in the grinding process, the grinding process can be performed outside ends of a first inorganic encapsulation layer and a second inorganic encapsulation layer disposed on the substrate. In this case, a process margin for the first inorganic encapsulation layer and the second inorganic encapsulation layer needs to be considered. Therefore, the size of the bezel area of the display device can be increased after the grinding process. In this case, when a tiling display device is manufactured by using a plurality of display devices, a boundary between the display devices can be visibly recognized by the user.

Thus, the first inorganic encapsulation layer and the second inorganic encapsulation layer disposed on the substrate can be ground together with the substrate in consideration of the process margin during the grinding process. However, an inorganic material is very sensitive to external impacts. Therefore, during the grinding process, cracks can occur in the first inorganic encapsulation layer and the second inorganic encapsulation layer. The cracks can be propagated to a display area as well as a non-display area. When the cracks occur in the first inorganic encapsulation layer and the second inorganic encapsulation layer, moisture and oxygen can permeate into the display device.

Thus, in the electroluminescent display device 100 according to an example embodiment of the present disclosure, the first structure ST1 is disposed in the non-display area NA to separate the first inorganic encapsulation layer 121 and the second inorganic encapsulation layer 123 in the non-display area NA. As described above with reference to FIG. 4, each of the first inorganic encapsulation layer 121 and the second inorganic encapsulation layer 123 can be separated with respect to the first structure ST1. For example, each of the first inorganic encapsulation layer 121 and the second inorganic encapsulation layer 123 can be disconnected by an undercut shape of the first structure ST1 during a manufacturing process. Therefore, the first inorganic encapsulation layer 121 and the second inorganic encapsulation layer 123 can be ground together with the substrate 101 during a grinding process to minimize the size of a bezel area. Thus, even when cracks occur in the first inorganic encapsulation layer 121 and the second inorganic encapsulation layer 123 disposed adjacent to the end of the substrate 101, the cracks may not be propagated to the first inorganic encapsulation layer 121 and the second inorganic encapsulation layer 123 disposed more adjacent to the display area AA than the first structure ST1. Therefore, in the electroluminescent display device 100 according to an example embodiment of the present disclosure, it is possible to minimize the permeation of moisture and oxygen into the electroluminescent display device 100.

Further, in the electroluminescent display device 100 according to an example embodiment of the present disclosure, the first inorganic encapsulation layer 121 and the second inorganic encapsulation layer 123 are ground together with the substrate 101. Thus, the size of the bezel area of the electroluminescent display device 100 can be designed regardless of the process margin for the first inorganic encapsulation layer 121 and the second inorganic encapsulation layer 123. Therefore, the size of the bezel area can be minimized during the process of grinding an outer region of the electroluminescent display device 100. Thus, a more comfortable margin can be secured. Accordingly, the size of the non-display area NA can be reduced and a narrow bezel can be implemented.

Furthermore, in the electroluminescent display device 100 according to an example embodiment of the present disclosure, the anode 151 includes the first anode 151a and the second anode 151b. Since the electroluminescent display device 100 according to an example embodiment of the present disclosure is a top emission electroluminescent display device, the anode 151 needs to contain a material with high reflectivity. Thus, the anode 151 can include the second anode 151b in which a layer made of indium tin oxide (ITO), a layer made of silver (Ag) or an Ag alloy, and a layer made of ITO are laminated. However, silver (Ag) is easily etched by an etchant which is used for etching other components than the second anode 151b. Therefore, when the plurality of structures ST is formed by using the second anode 151b, undercut shapes of the plurality of structures ST can be lost during a manufacturing process. As such, in the electroluminescent display device 100 according to an example embodiment of the present disclosure, the anode 151 includes the first anode 151a having a structure in which a layer made of indium tin oxide (ITO), a layer made of a molybdenum-titanium (MoTi) alloy, and a layer made of ITO are laminated. Further, each of the first structure ST1, the second structure ST2, and the fourth structure ST4 can include a layer made of the same material as the first anode 151a. Therefore, in the electroluminescent display device 100 according to an example embodiment of the present disclosure, the reflectivity of the anode 151 can be maintained, and the undercut shapes of the plurality of structures ST can also be maintained.

Furthermore, in the electroluminescent display device 100 according to an example embodiment of the present disclosure, the second anode 151b with high reflectivity and high electrical conductivity is laminated on the first anode 151a in the display area AA. Thus, a resistance of the anode 151 in the display area AA can be reduced and the electrical conductivity can be improved. The MoTi alloy, which is a material of the first anode 151a, can have a lower reflectivity and a lower electrical conductivity than other metal materials. As such, the second anode 151b made of a material, such as an Ag alloy, with high reflectivity and high electrical conductivity is laminated in the display area AA. Therefore, a resistance of the anode 151 in the display area AA can be reduced and the electrical conductivity can be improved.

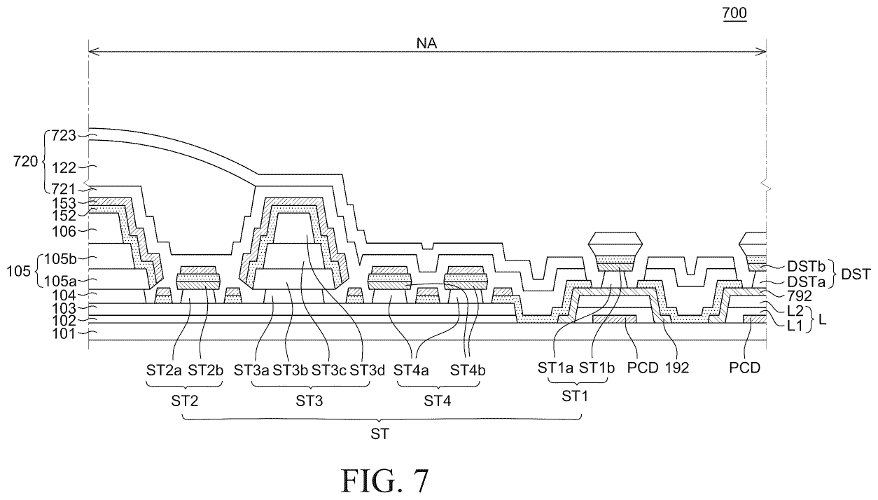

FIG. 7 is a cross-sectional view of an electroluminescent display device according to another example embodiment of the present disclosure. Particularly, FIG. 7 is a cross-sectional view of the other surfaces of the substrate 101 except the one surface on which the flexible films 160 are disposed. An electroluminescent display device 700 shown in FIG. 7 is substantially the same as the electroluminescent display device 100 shown in FIG. 1 through FIG. 6 except the crack detection unit PCD, the plurality of inorganic layers L, a transparent conductive layer 792, a first inorganic encapsulation layer 721, a second inorganic encapsulation layer 723, and the addition of a dummy structure DST. Therefore, redundant description thereof will be omitted or briefly provided.

Referring to FIG. 7, the crack detection unit PCD can be disposed outside the fourth structure ST4 on the substrate 101.

The crack detection unit PCD can be disposed under the first structure ST1 and the dummy structure DST so as to overlap the first structure ST1 and the dummy structure DST. Herein, an end of the crack detection unit PCD can overlap the end of the substrate 101.

The plurality of inorganic layers L can be disposed on the crack detection unit PCD. The plurality of inorganic layers L can be disposed in a region overlapping the first structure ST1 so as to cover side and upper surfaces of the crack detection unit PCD.

The plurality of inorganic layers L can be disposed in a region overlapping the dummy structure DST so as to cover the upper surface of the crack detection unit PCD and a side surface of the crack detection unit PCD. Herein, ends of the plurality of inorganic layers L can be disposed to overlap the other side surface of the crack detection unit PCD. For example, the ends of the plurality of inorganic layers L can overlap the end of the crack detection unit PCD and the end of the substrate 101.

The transparent conductive layer 792 can be disposed between the plurality of inorganic layers L and the first structure ST1 and between the plurality of inorganic layers L and the dummy structure DST on the substrate 101.

The transparent conductive layer 792 can be disposed in a region overlapping the first structure ST1 so as to enclose upper and side surfaces of the plurality of inorganic layers L disposed on the crack detection unit PCD. Further, the transparent conductive layer 792 can be disposed to be in contact with the upper surface of the substrate 101.

Further, the transparent conductive layer 792 can be disposed in a region overlapping the dummy structure DST so as to enclose the upper surfaces of the plurality of inorganic layers L and one side surfaces of the plurality of inorganic layers L disposed on the crack detection unit PCD. Furthermore, the transparent conductive layer 792 can be disposed to be in contact with the upper surface of the substrate 101. Herein, an end of the transparent conductive layer 792 can overlap ends of the plurality of inorganic layers L and the end of the crack detection unit PCD.

The dummy structure DST can be disposed on the other surfaces of the substrate 101 except the one surface on which the flexible films 160 are disposed as shown in FIG. 7. Further, the dummy structure DST can be disposed more adjacent to the outermost region of the substrate 101 than the first structure ST1.

Meanwhile, the dummy structure DST can have a shape corresponding to a part of the first structure ST1. For example, the dummy structure DST can have the same shape as the first structure ST1 from which a portion adjacent to an outer region of the substrate 101 has been removed. For example, the dummy structure DST can be the same as the first structure ST1 remaining after the process of grinding the substrate 101 to the same size as the electroluminescent display device 700.

The dummy structure DST can include a first layer DSTa and a second layer DSTb on the first layer DSTa. Further, a lower surface of the second layer DSTb can have a greater size than an upper surface of the first layer DSTa.

The first layer DSTa of the dummy structure DST can be made of the same material as an insulating layer covering upper portions of the plurality of transistors 110, and the second layer DSTb can be made of the same material as the anode 151. For example, the first layer DSTa of the dummy structure DST can be made of the same material as the passivation layer 104. For example, the first layer DSTa can be made of an inorganic insulating material, such as silicon oxide (Siox) or silicon nitride (SiNx). The second layer DSTb can be made of the same material as the first anode 151a. For example, the second layer DSTb can have a structure in which a layer made of indium tin oxide (ITO), a layer made of a molybdenum-titanium (MoTi) alloy, and a layer made of ITO are laminated. However, the present disclosure is not limited thereto.

Each of the first inorganic encapsulation layer 721 and the second inorganic encapsulation layer 723 can be separated with respect to the first structure ST1 and the dummy structure DST.

The end of the substrate 101 can overlap the end of the crack detection unit PCD, the ends of the plurality of inorganic layers L, the end of the transparent conductive layer 792, the end of the emission layer 152, an end of the first inorganic encapsulation layer 721, an end of the second inorganic encapsulation layer 723, and an end of the dummy structure DST.

In the electroluminescent display device 700 according to another example embodiment of the present disclosure, the first structure ST1 is disposed in the non-display area NA. Thus, each of the first inorganic encapsulation layer 721 and the second inorganic encapsulation layer 723 can be disconnected by the undercut shape of the first structure ST1. Therefore, it is possible to minimize the permeation of moisture and oxygen into the electroluminescent display device 700.

Further, in the electroluminescent display device 700 according to another example embodiment of the present disclosure, the first inorganic encapsulation layer 721 and the second inorganic encapsulation layer 723 are ground together with the substrate 101. Accordingly, the size of the non-display area NA can be reduced and a narrow bezel can be implemented.

Furthermore, in the electroluminescent display device 700 according to another example embodiment of the present disclosure, the anode 151 includes the first anode 151a and the second anode 151b. Accordingly, the reflectivity of the anode 151 can be maintained, and the undercut shapes of the plurality of structures ST can also be maintained.

In addition, in the electroluminescent display device 700 according to another example embodiment of the present disclosure, the second anode 151b with high reflectivity and high electrical conductivity is laminated on the first anode 151a in the display area AA. Accordingly, a resistance of the anode 151 in the display area AA can be reduced and the electrical conductivity can be improved.

Further, in the electroluminescent display device 700 according to another example embodiment of the present disclosure, the dummy structure DST is disposed to have a shape corresponding to a part of the first structure ST1. The dummy structure DST can be the same as the first structure ST1 remaining after the process of grinding the substrate 101 to the same size as the electroluminescent display device 700. Thus, each of the first inorganic encapsulation layer 721 and the second inorganic encapsulation layer 723 separated with respect to the first structure ST1 can be further separated with respect to the dummy structure DST.

Therefore, even when the first inorganic encapsulation layer 721 and the second inorganic encapsulation layer 723 are ground together with the substrate 101 during the grinding process, the propagation of cracks occurring in the first inorganic encapsulation layer 721 and the second inorganic encapsulation layer 723 to the first inorganic encapsulation layer 121 and the second inorganic encapsulation layer 123 disposed adjacent to the display area AA can be effectively suppressed, minimized or eliminated. Accordingly, in the electroluminescent display device 700 according to another example embodiment of the present disclosure, it is possible to effectively suppress the permeation of moisture and oxygen into the electroluminescent display device 700.

The example embodiments of the present disclosure can also be described as follows:

According to an aspect of the present disclosure, there is provided an electroluminescent display device. The electroluminescent display device comprises a substrate including a display area and a non-display area enclosing the display area, a plurality of transistors disposed in the display area on the substrate, a light emitting diode connected to the plurality of transistors and including an anode, an emission layer, and a cathode, an encapsulation layer disposed on the light emitting diode and including a first inorganic encapsulation layer, an organic encapsulation layer disposed on the first inorganic encapsulation layer, and a second inorganic encapsulation layer disposed on the organic encapsulation layer, and a plurality of structures disposed in the non-display area on the substrate. Each of the first inorganic encapsulation layer and the second inorganic encapsulation layer is separated with respect to a first structure disposed in an outermost region of the substrate among the plurality of structures.

An end of the substrate can overlap an end of the emission layer, an end of the first inorganic encapsulation layer, and an end of the second inorganic encapsulation layer.

The first structure can include a first layer and a second layer disposed on the first layer, and a lower surface of the second layer can have a greater size than an upper surface of the first layer.

The electroluminescent display device can further comprise an insulating layer disposed on the substrate and covering upper portions of the plurality of transistors. The first layer can be made of the same material as the insulating layer, and the second layer can be made of the same material as the anode.

The anode can include a first anode in which a layer made of indium tin oxide (ITO), a layer made of an molybdenum-titanium (MoTi) alloy, and a layer made of ITO are laminated, and a second anode which is disposed on the first anode and in which a layer made of ITO, a layer made of silver (Ag) or an Ag alloy, and a layer made of ITO are laminated. The second layer can be made of the same material as the first anode.

The electroluminescent display device can further comprise a dummy structure disposed overlapping an end of the substrate, wherein the dummy structure can have a shape corresponding to a part of the first structure.

The plurality of structures can include a second structure, a third structure disposed outside the second structure, and a fourth structure disposed between the third structure and the first structure. The second structure can be the same as the fourth structure. The third structure can have a greater height than the second structure and the fourth structure.

The electroluminescent display device can further comprise a passivation layer disposed on the substrate and covering upper portions of the plurality of transistors. The electroluminescent display device can further comprise a planarization layer disposed on the passivation layer so as to planarize an r portion of the passivation layer. The electroluminescent display device can further comprise a bank disposed on the planarization layer and the anode. Each of the second structure and the fourth structure can have a structure in which the same material as the passivation layer and the same material as the anode are laminated. The third structure can have a structure in which the same material as the passivation layer, the same material as the planarization layer, and the same material as the bank are laminated.

The second structure can be disposed under the organic encapsulation layer. An end of the organic encapsulation layer can be disposed to overlap the third structure.

Each of the first inorganic encapsulation layer and the second inorganic encapsulation layer can be continuously disposed to be in contact with surfaces of the second structure, the third structure, and the fourth structure.

The electroluminescent display device can further comprise a flexible film bonded to one surface of the substrate. The first structure can be disposed on the other surfaces of the substrate except the one surface on which the flexible film is disposed.

The electroluminescent display device can further comprise a crack detection unit disposed under the plurality of structures so as to overlap the first structure.

The electroluminescent display device can further comprise a plurality of inorganic layers disposed between the crack detection unit and the structure on the substrate. The plurality of inorganic layers can be disposed to cover side and upper surfaces of the crack detection unit.

The plurality of inorganic layers can be made of the same material as inorganic insulating layers disposed in the display area.

The electroluminescent display device can further comprise a transparent conductive layer disposed between the plurality of inorganic layers and the structure on the substrate. The transparent conductive layer can be disposed to enclose upper and side surfaces of the plurality of inorganic layers and disposed to be in contact with an upper surface of the substrate.

The electroluminescent display device can further comprise a plurality of pads disposed on one surface of the substrate, and a pad protection layer disposed to enclose the plurality of pads and made of the same material as the transparent conductive layer.

According to another aspect of the present disclosure, there is provided an electroluminescent display device. The electroluminescent display device comprises a substrate including a display area and a non-display area enclosing the display area. The electroluminescent display device comprises a plurality of transistors disposed in the display area on the substrate. The electroluminescent display device comprises a light emitting diode connected to the plurality of transistors and including an anode, an emission layer, and a cathode. The electroluminescent display device comprises an encapsulation layer disposed on the light emitting diode and including a first inorganic encapsulation layer, an organic encapsulation layer disposed on the first inorganic encapsulation layer, and a second inorganic encapsulation layer disposed on the organic encapsulation layer. The electroluminescent display device comprises an undercut structure disposed in an outermost region of the substrate in the non-display area. Each of the first inorganic encapsulation layer and the second inorganic encapsulation layer is separated with respect to the undercut structure.

An end of the substrate can be disposed on the same plane as an end of the emission layer, an end of the first inorganic encapsulation layer, and an end of the second inorganic encapsulation layer.

The electroluminescent display device can further comprise a plurality of structures disposed more adjacent to the display area than the undercut structure in the non-display area. Each of the first inorganic encapsulation layer and the second inorganic encapsulation layer can be continuously disposed to be in contact with surfaces of the plurality of structures.

The plurality of structures can include a dam enclosing the organic encapsulation layer, and a structure which is disposed inside and outside the dam and of which an upper surface has a greater size than a lower surface.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. An electroluminescent display device, comprising:
a substrate including a display area and a non-display area adjacent to the display area;
a plurality of transistors disposed in the display area on the substrate;
a light emitting diode connected to the plurality of transistors and including an anode, an emission layer, and a cathode;
an encapsulation layer disposed on the light emitting diode and including a first inorganic encapsulation layer, an organic encapsulation layer disposed on the first inorganic encapsulation layer, and a second inorganic encapsulation layer disposed on the organic encapsulation layer; and
a plurality of structures disposed in the non-display area on the substrate,
wherein each of the first inorganic encapsulation layer and the second inorganic encapsulation layer is separated with respect to a first structure disposed in an outermost region of the substrate among the plurality of structures.

2. The electroluminescent display device according to claim 1, wherein an end of the substrate overlaps an end of the emission layer, an end of the first inorganic encapsulation layer, and an end of the second inorganic encapsulation layer.

3. The electroluminescent display device according to claim 1, wherein the first structure among the plurality of structures includes a first layer and a second layer disposed on the first layer, and
wherein a lower surface of the second layer has a greater size than an upper surface of the first layer.

4. The electroluminescent display device according to claim 3, further comprising:
an insulating layer disposed on the substrate and covering upper portions of the plurality of transistors,
wherein the first layer is made of a same material as the insulating layer, and the second layer is made of a same material as the anode.

5. The electroluminescent display device according to claim 4, wherein the anode includes:
a first anode in which a layer made of indium tin oxide (ITO), a layer made of an molybdenum-titanium (MoTi) alloy, and a layer made of ITO are laminated, and
a second anode which is disposed on the first anode and in which a layer made of ITO, a layer made of silver (Ag) or an Ag alloy, and a layer made of ITO are laminated, and
wherein the second layer is made of a same material as the first anode.

6. The electroluminescent display device according to claim 1, further comprising:
a dummy structure overlapping an end of the substrate,
wherein the dummy structure has a shape corresponding to a part of the first structure.

7. The electroluminescent display device according to claim 1, wherein the plurality of structures includes a second structure, a third structure disposed outside the second structure, and a fourth structure disposed between the third structure and the first structure,
wherein the second structure is same as the fourth structure, and
wherein the third structure has a greater height than the second structure and the fourth structure.

8. The electroluminescent display device according to claim 7, further comprising:
a passivation layer disposed on the substrate and covering upper portions of the plurality of transistors;
a planarization layer disposed on the passivation layer so as to planarize an upper portion of the passivation layer; and
a bank disposed on the planarization layer and the anode,
wherein each of the second structure and the fourth structure has a structure in which a same material as the passivation layer and a same material as the anode are laminated, and
wherein the third structure has a structure in which a same material as the passivation layer, a same material as the planarization layer, and a same material as the bank are laminated.

9. The electroluminescent display device according to claim 7, wherein the second structure is disposed under the organic encapsulation layer, and
wherein an end of the organic encapsulation layer is disposed to overlap the third structure.

10. The electroluminescent display device according to claim 7, wherein each of the first inorganic encapsulation layer and the second inorganic encapsulation layer is continuously disposed to be in contact with surfaces of the second structure, the third structure, and the fourth structure.

11. The electroluminescent display device according to claim 1, further comprising:
a flexible film bonded to one surface of the substrate,
wherein the first structure is disposed on other surfaces of the substrate except the one surface of the substrate on which the flexible film is disposed.

12. The electroluminescent display device according to claim 1, further comprising:
a crack detection unit disposed under the plurality of structures so as to overlap the first structure.

13. The electroluminescent display device according to claim 12, further comprising:
a plurality of inorganic layers disposed between the crack detection unit and the first structure on the substrate,
wherein the plurality of inorganic layers is disposed to cover side and upper surfaces of the crack detection unit.

14. The electroluminescent display device according to claim 13, wherein the plurality of inorganic layers is made of a same material as inorganic insulating layers disposed in the display area.

15. The electroluminescent display device according to claim 13, further comprising:
a transparent conductive layer disposed between the plurality of inorganic layers and the structure on the substrate,
wherein the transparent conductive layer is disposed to enclose upper and side surfaces of the plurality of inorganic layers and disposed to be in contact with an upper surface of the substrate.

16. The electroluminescent display device according to claim 15, further comprising:
a plurality of pads disposed on one surface of the substrate; and
a pad protection layer disposed to enclose the plurality of pads and made of a same material as the transparent conductive layer.

17. An electroluminescent display device, comprising:
a substrate including a display area and a non-display area adjacent to the display area;
a plurality of transistors disposed in the display area on the substrate;
a light emitting diode connected to the plurality of transistors and including an anode, an emission layer, and a cathode;
an encapsulation layer disposed on the light emitting diode and including a first inorganic encapsulation layer, an organic encapsulation layer disposed on the first inorganic encapsulation layer, and a second inorganic encapsulation layer disposed on the organic encapsulation layer; and
an undercut structure disposed in an outermost region of the substrate in the non-display area,
wherein each of the first inorganic encapsulation layer and the second inorganic encapsulation layer is separated with respect to the undercut structure.

18. The electroluminescent display device according to claim 17, wherein an end of the substrate is disposed on a same plane as an end of the emission layer, an end of the first inorganic encapsulation, and an end of the second inorganic encapsulation layer.

19. The electroluminescent display device according to claim 17, further comprising:
a plurality of structures disposed more adjacent to the display area than the undercut structure in the non-display area,
wherein each of the first inorganic encapsulation layer and the second inorganic encapsulation layer is continuously disposed to be in contact with surfaces of the plurality of structures.

20. The electroluminescent display device according to claim 19, wherein the plurality of structures includes a dam enclosing the organic encapsulation layer, and a structure disposed inside and outside the dam and including an upper surface having a greater size than a lower surface of the structure.
